(19) United States
(12) Patent Application Publication
(10) Pub. No.: US 2011/0018064 A1
(43) Pub. Date: Jan. 27, 2011

(54) SRAM CELL COMPRISING FINFETS

(75) Inventor: Gerben Doornbos, Kessel-Lo (BE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/935,961

(22) PCT Filed: Mar. 31, 2009
(86) PCT No.: PCT/IB2009/051338

§ 371 Date: Oct. 1, 2010

(30) Foreign Application Priority Data
Apr. 4, 2008 (EP) 08103378.9

(51) Int. Cl. H01L 29/772; H01L 21/336

(52) U.S. Cl. 257/365; 438/279; 257/E29.242; 257/E21.409

(57) ABSTRACT

An SRAM finFET cell includes fins (30 . . . 40) and respective insulated gates (62 . . . 72) forming finFET transistors, together with interconnects (86 . . . 92) connecting the fins and gates. The regions of the fins not covered by the insulated gates are doped. Each of the fins (30 . . . 40) extends in the same longitudinal direction; and each of the fins (30 . . . 40) is arranged laterally adjacent to another fin of the same conductivity type. The cell design reduces the effects of process spread.

The invention relates to an static random access memory (SRAM) cell design, particularly to an SRAM cell design suitable for use with narrow field effect transistors (FETs).

As CMOS scaling is reduced below the 45 nm node, conventional bulk MOSFETs become less suitable and alternatives are envisaged. In order to reduce short channel effects, gate control over the silicon channel may be enhanced. Two alternative technologies are foreseen. Firstly, fully-depleted silicon on insulator (FDSOI) technology may be used, in which planar transistors are built on SOI substrates with extremely thin silicon layers (less than 10 nm). Secondly, multigate FETs (MuGFETs) may be used in which thin silicon channels are controlled by gates on two or more sides.

For CMOS nodes beyond 32 nm, uGFETs are seen as the best scalable option and so much research activity is presently directed in this area.

A particularly attractive MuGFET is the so-called finFET, with a vertical fin-shaped channel. The advantages are the natural self-alignment of front and back gates, as well as processing that is fairly similar to conventional bulk processing. Such finFETs may typically be formed on SOI substrates, though they may also be formed on bulk Si substrates.

A key issue in finFET technology is the access resistance which results from the section of the narrow fin between the source and drain contacts and the gate edge. To reduce this resistance, it is important to dope the fin all the way to the bottom, which is conventionally done using a high-tilt doping technique in which the dopants are applied from a tilt angle.

Typically, the best trade-off is achieved with tilt angles of about 45°, doping the fin on both left and right sides. This gives similar doping profiles on the top and sides of the fin. Given a 100 nm fin pitch and 60 nm fin height, no shadowing occurs.

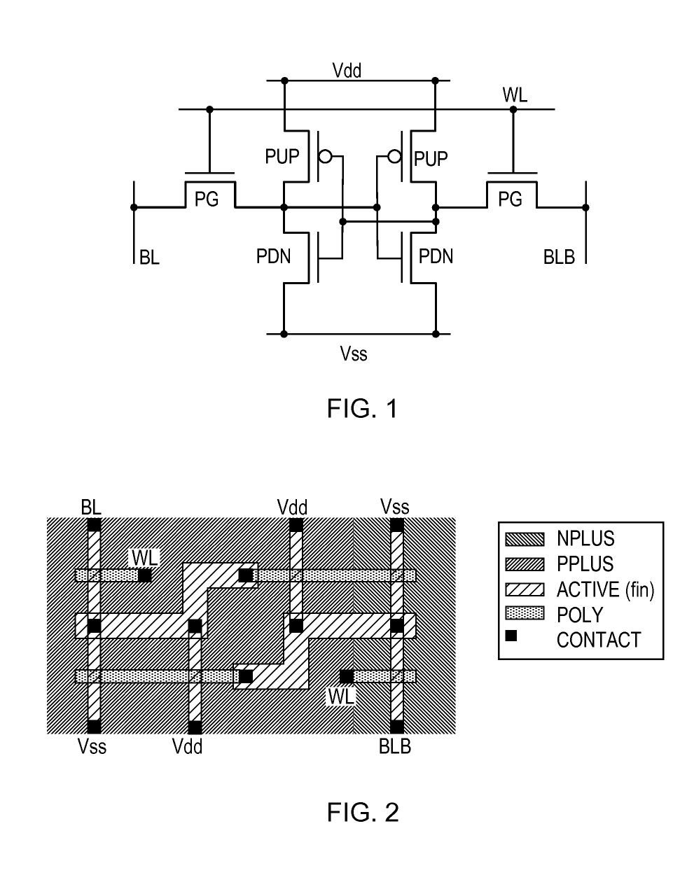

Such FETs are of course not used on their own but in combination as circuits. A particular very important circuit is the SRAM cell. FIG. 1 shows a six transistor (6T) SRAM which uses two cross-coupled inverters, each consisting of a PMOS pull-up transistor (PUP) and an NMOS pull-down transistor (PDN), with pass gates (PG) which connect the inverters to the bit line (BL) and bit line bar (BLB) interconnects. The circuit is powered from the power lines (Vdd and Vss).

According to the invention, there is provided an SRAM cell according to claim 1.

The inventors have realized that since the fins extend in the same (longitudinal) direction and are only laterally adjacent to other fins of the same conductivity type, a problem of resist masking does not occur.

To explain, resist masking occurs in a finFET where one fin is to be p-type and an adjacent fin n-type. During a p-type implantation process, the n-type fin needs to be covered in resist. Unfortunately, this resist is close to the first fin and removes the possibility of doping the fin at a high tilt angle of say 45°. Instead, a lower tilt angle needs to be used to avoid the resist masking the adjacent fin which leads to non-conformal (uneven) doping profiles. A further problem with having resist on an adjacent fin during implantation, is that slight misalignment of the resist can cause the resist to be closer to the fin being doped. This can partially shadow the fin. This misalignment is known as an overlay error and the partial shadowing is a source of process spread, leading to transistor mismatch.

Thus, by aligning the fins with adjacent fins being of the same conductivity type, these problems can be avoided.

Thus, by using the invention fins can be manufactured to a minimum fin pitch.

The inventors have also realized that, contrary to conventional CMOS design, in a finFET the pull-up and pull-down transistors may share a common drain contact, enabling a pair of pull-up and pull-down transistors to be formed as a single unbroken longitudinal line, with a common contact in the centre dividing the pull-up and pull-down transistors. This is possible since the pull-up and pull-down transistors can be doped to be of opposite conductivity type without requiring a gap between them.

A six-transistor SRAM cell may be manufactured with six fins each extending in the same longitudinal direction and six insulated gates extending laterally across the respective fins to form six respective finFET transistors. The fins can be arranged as longitudinally aligned first, second and third fins, and longitudinally aligned fourth, fifth and sixth fins, the first, second and third fins being laterally adjacent to the fourth, fifth and sixth fins respectively. In this case, the laterally adjacent first and fourth fins may be doped to be the first conductivity type and the second, third, fifth and sixth fins are doped to be the second conductivity type.

The invention also relates to specific SRAM cell layouts.

In an aspect, the invention relates to the manufacture of the SRAM cells as set out above.

For a better understanding of the invention, embodiments will now be described with reference to the accompanying drawings, in which:

FIG. 1 shows a circuit diagram of a six transistor SRAM cell;

FIG. 2 illustrates a possible layout using finFETs as a comparative example;

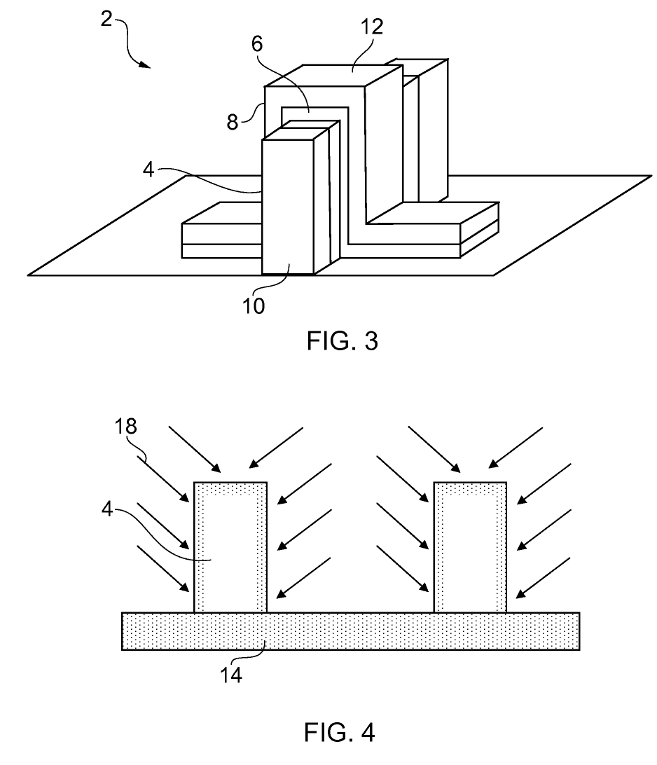

FIG. 3 illustrates a finFET as used in embodiments of the invention;

FIG. 4 illustrates a doping process used in the manufacture of a finFET;

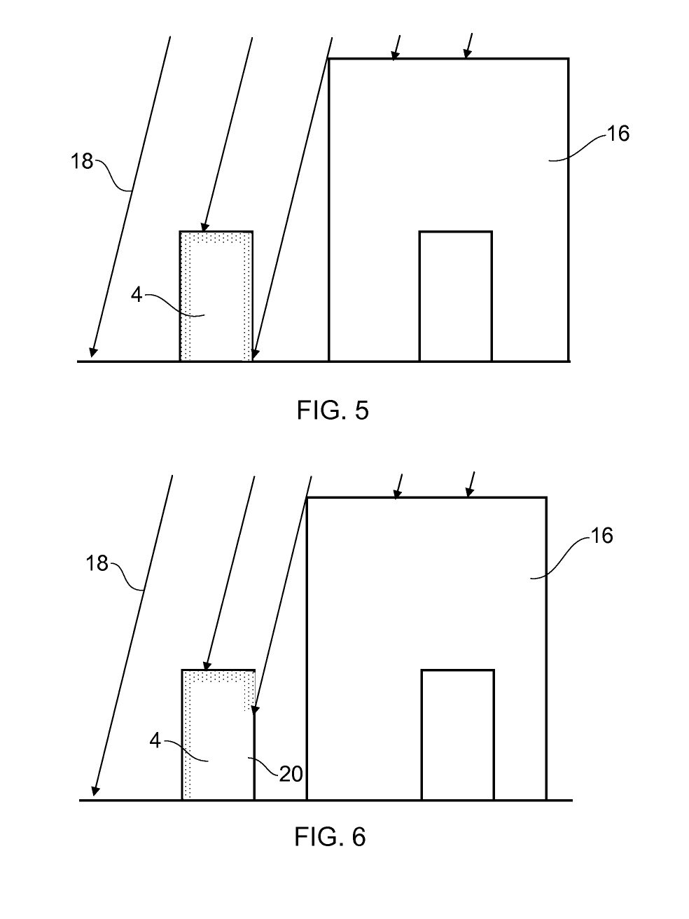

FIG. 5 ilustrates the higher tilt doping required in certain cases;

FIG. 6 illustrates the effects of resist misalignment;

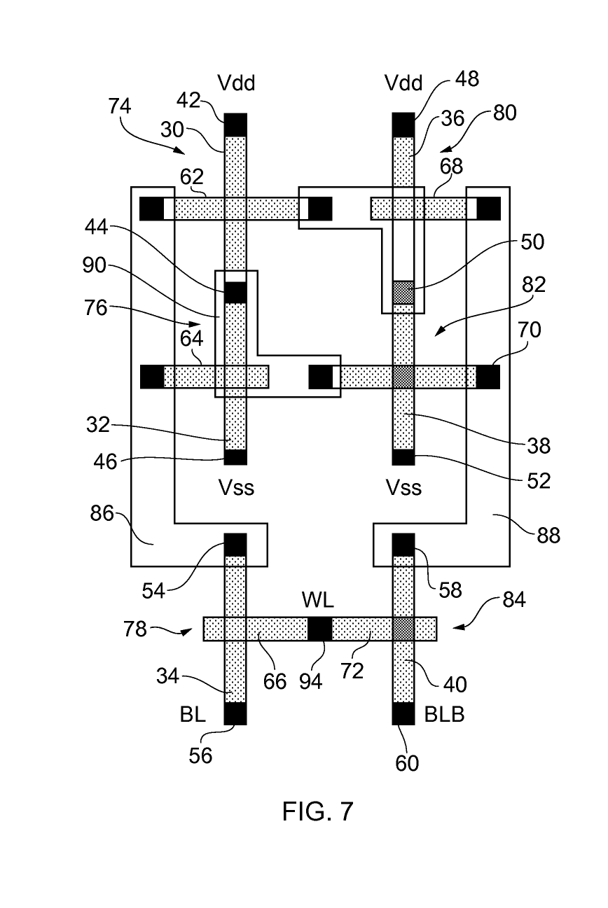

FIG. 7 illustrates the layout of a finFET cell according to a first embodiment;

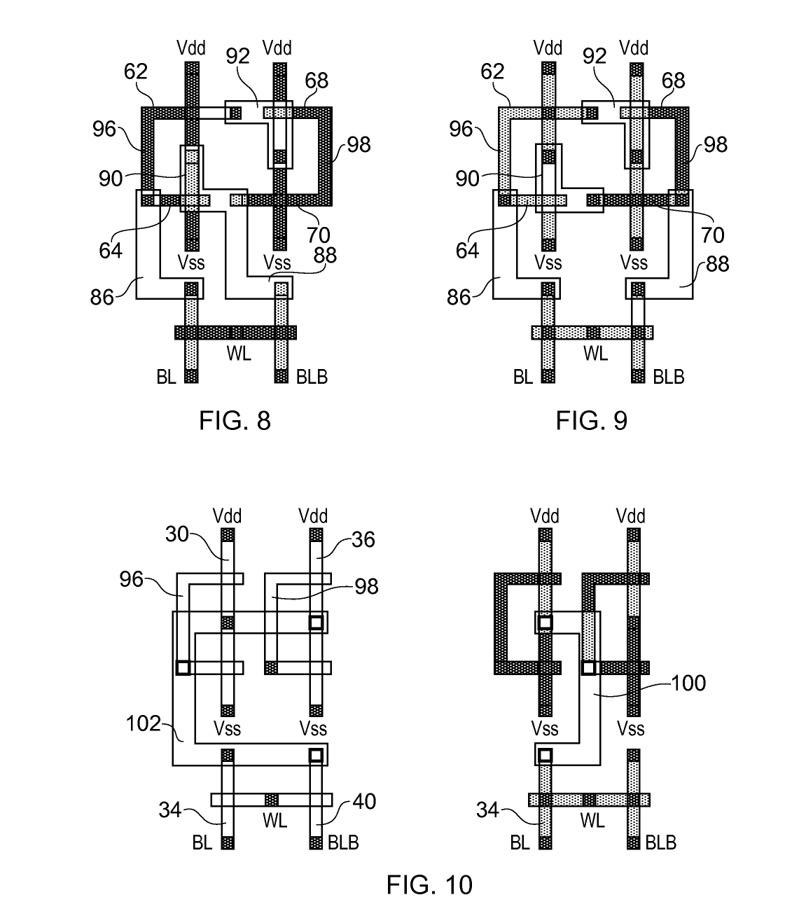

FIG. 8 illustrates the layout of a finFET cell according to a second embodiment;

FIG. 9 illustrates the layout of a finFET cell according to a third embodiment;

FIG. 10 illustrates the layout of a finFET cell according to a fourth embodiment; and

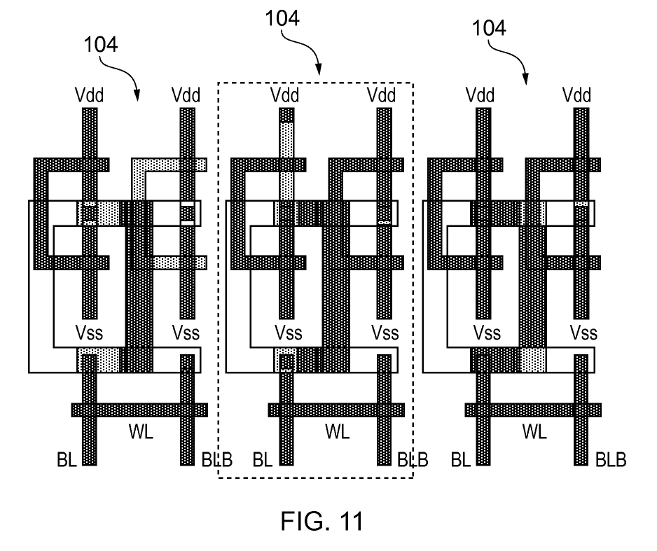

FIG. 11 illustrates an array of cells.

The drawings are schematic and not to scale. The same or corresponding features are given the same reference numerals in different figures.

A first attempt to manufacture a six transistor SRAM cell, such as that shown in FIG. 1, using finFETs, might be as shown in FIG. 2, a comparative example. This is based in part on A. Nackaerts et al., IEDM Digest, pp. 269-272, 2004, and has a layout which is a direct translation from the conventional planar bulk CMOS arrangement. However, this cell has proven difficult to manufacture. In particular, process spread can cause transistor failure.

Referring to FIG. 3, a perspective view of a single finFET 2 is shown having a fin 4, a very thin gate insulator 6 and a polysilicon gate 8 extending over the fin 4 and insulator 6. Typical dimensions might be a gate length of 30 nm, fin height of 60 nm and fin width of 10 nm, though these will vary depending on the exact process. Source and drain contacts 10, 12 are provided on each end of the fin.

The parts of the fins 4 between the source and drain contacts 10, 12 and the gate 8 need to be doped in order to reduce the series resistance of the finFET. This series resistance is the major contributor to the high parasitic access resistance, a significant issue for finFET technology, and accordingly reducing the series resistance is a major concern.

Typically, this is achieved by doping the fins using a high-tilt angle doping technique as illustrated in FIG. 4, which shows a pair of fins 4 on a buried oxide layer 14. The fins are doped with dopant 18 using a tilt angle of around 45°, firstly from one side of the fin and secondly from the other side. This gives relatively similar doping profiles on the walls and tops of the fins.

The fins in the example are 100 nm apart and 60 nm high, so there is no shadowing from one fin of the other fin during the doping process.

Note however, as illustrated in FIG. 5, that where the adjacent fins are to be doped with opposite conductivity types, i.e. n-type and p-type, the p-type fin needs to be masked with resist 16 while the n-type doping takes place, and vice versa. The resist height needs to be considerably higner than the 60 nm fin height, and is also closer to the adjacent fin. This means that 45° tilt angle doping can no longer be used. The lower tilt angle results in a non-conformal doping profile of the fin.

Further, as illustrated in FIG. 6, if the resist 16 is slightly misaligned additional shadowing may occur and this can lead to part of the fin 20 not being doped at all.

Accordingly, the inventors have realised that the kinds of problem illustrated in FIGS. 5 and 6 cause a real problem with the prior art arrangement of FIG. 2.

The inventors have therefore designed alternative layouts according to a number of embodiments. Referring to FIGS. 7, 8 and 9, FIG. 7 shows a plurality of fins aligned in two longitudinal lines (shown vertically in the Figures), laterally adjacent to one another.

The first line includes longitudinally aligned first 30, second 32 and third 34 fins, the first and second fins 30, 32 being joined together and the third fin 34 being longitudinally spaced from the second fin 32. The first fin extends between a high voltage contact (42, Vdd) and a first common drain contact 44, and the second fin extends between the first common drain contact 44 and a low voltage contact (46, Vss). The third fin extends between a first centre point contact 54 and a bit line contact 56.

The second line includes longitudinally aligned fourth 36, fifth 38 and sixth 40 fins, arranged laterally adjacent to the first 30, second 32 and third 34 fins respectively. The fourth and fifth fins 36, 38 are joined together and the sixth fin 40 is longitudinally spaced from the fifth fin 38.

The fourth fin 36 extends between a high voltage contact (48, Vdd) and a second common drain contact 50, and the fifth fin extends between the common drain contact 50 and a low voltage conact (52, Vss). The sixth fin extends between a second centre point contact 58 and a bit line bar (BLB) contact 60.

The first and fourth fins are doped p-type, and the remaining fins n-type. Thus, each fin is laterally adjacent to a fin of the same conductivity type, and all fins extend in the same longitudinal direction.

A polysilicon layer provides the gates over the fins and may, in embodiments, also be used as an interconnect.

In the FIG. 7 arrangement, first 62, second 64, third 66, fourth 68, fifth 70 and sixth 72 polysilicon gates are provided over the first to sixth fins 30, 32, 34, 36, 38, 40 respectively to define first through sixth finFET transistors 74, 76, 78, 80, 82, 84 respectively.

Additional interconnect is provided in a further metallisation layer, having a plurality of metallisation regions.

A first region 86 connects the first gate 62, the second gate 64, and the first centre point contact 54. These elements are also connected via the other end of the first gate and a fourth region 92 to the second common drain contact 50.

A second region 88 connects the fourth gate 68, the fifth gate 70, and the second centre point contact 58. These elements are also connected via the other end of the fifth gate 70 and a third region 90 to the first common drain contact 44.

A word line contact 94 connects to the third and sixth gates 66, 72.

In this way, a six-transistor SRAM cell is provided with all the fins aligned in the same direction and with fins only being adjacent to other fins of the same conductivity type. This greatly eases manufacture since it avoids the low tilt angle required with close fins of opposite conductivity type and also the effects of resist misalignment which also occurs.

FIG. 8 shows an alternative arrangements. Each of these use the polysilicon layer to provide parts of the interconnects. In particular, a first polysilicon extension 96 extends longitudinally between the first and second gates 62, 64 to connect them together. A second polysilicon extension 98 extends longitudinally between the fourth and fifth gates 68, 70 to connect them together.

This allows less length of metallisation in the metallisation regions 86, 88.

FIG. 9 shows a further alternative arrangement, similar to FIG. 8 in using polysilicon extensions 96, 98 to connect the first and second gates together and the fourth and fifth gates together.

FIG. 10 shows the use of an alternative metallisation scheme on two separate levels. A first metallisation 100 connects the second polysilicon extension 98 to the first common drain contact 44 and the first centre point contact 54. A second metallisation 102 on a different layer connects the first polysilicon extension 96 to the second common drain contact 50 and the second centre point contact 58. Note in this case that the first and second gate extensions 96, 98 are on the same side of the first and fourth fins 30, 36 respectively, so one gate extension 98 is between the fins and the other 96 to the side.

The advantage of the FIG. 10 arrangement is that each cell has a reduced area, thereby increasing the density of cells.

FIG. 11 illustrates an SRAM array made up of a plurality of the SRAM cells 104 of FIG. 10. Note that the lateral spacing of fins is constant, i.e. the spacing of the closest fins in adjacent cells matches the spacing of fins within a cell. The first gate extensions 96 of all cells are between fins of adjacent cells and the second gate extensions 98 are between fins of the same cell.

The regular spacing of fins allows a particularly advantageous manufacturing technique. A completely regular array of fins is formed, extending longitudinally for the full length of the substrate and laterally spaced. Gaps are then formed in the fins of the array, to separate out the fins of longitudinally adjacent cells and also to separate out the pass gate transistor fins from the fins used to form the pull-up and pull-down transistors.

This approach allows the most reliable manufacture of fins at minimum possible feature sizes and spacing, and hence improves manufacturing reliability.

1. An SRAM finFET cell, comprising:
a plurality of fins;
a plurality of insulated gates extending across the respective fins to form respective finFET transistors; and
a plurality of interconnects connecting the fins and gates to define an SRAM cell;
wherein the regions of the fins not covered by the insulated gates are doped, some of the fins being doped a first conductivity type and others of the fins being doped a second conductivity type opposite to the first conductivity type;
each of the fins extends in the same longitudinal direction; and each of the fins is arranged laterally adjacent to another fin of the same conductivity type.

2. An SRAM cell according to claim 1, comprising at least one pair of fins extending longitudinally from a voltage contact to another voltage contact with a common drain contact midway between the voltage contacts, the fins of the pair being divided by the common drain contact and being oppositely doped to form a pull-up transistor and a pull-down transistor.

3. An SRAM cell according to claim 2 with six fins each extending in the same longitudinal direction and six insulated gates extending laterally across respective fins to form six respective finFET transistors; in which:
the first and second fins form a pair of fins in which the first fin extends longitudinally from a first voltage contact to a first common drain contact, and the second fin extends longitudinally from the first common drain contact to a second voltage contact;
the fourth and fifth fins form a pair of fins in which the fourth fin extends longitudinally from a third voltage contact to a second common drain contact, and the fifth fin extends longitudinally from the second common drain contact to a fourth voltage contact.

4. An SRAM cell according to claim 3 wherein the third and sixth insulated gates are connected to a common word line contact to form the gates of first and second pass-gate transistors.

5. An SRAM cell according to claim 3 wherein the first, second and third fins are laterally adjacent to the fourth, fifth and sixth fins respectively; and
the laterally adjacent first and fourth fins are doped to be a first conductivity type and the second, third, fifth and sixth fins are doped to be of a second conductivity type opposite to the first conductivity type.

6. An SRAM cell according to claim 1, with six fins each extending in the same longitudinal direction and six insulated gates extending laterally across respective fins to form six respective finFET transistors wherein:
the first fin extends longitudinally from a first voltage contact to the first common drain contact;
the second fin extends longitudinally from the first common drain contact to a second voltage contact;
the third fin is longitudinally spaced from the first and second fins and extends longitudinally between a bit line contact and a first centre point contact, the first, second and third fins being longitudinally aligned;
the fourth fin extends longitudinally from a third voltage contact to the second common drain contact;
the fifth fin extends longitudinally from the second common drain contact to a fourth voltage contact; and
the sixth fin is longitudinally spaced from the fourth and fifth fins and extends longitudinally between a second centre point contact and a second bit line contact, the fourth, fifth and sixth fins being longitudinally aligned; and
the interconnects include connectors which:
connect the first gate to the first centre point contact;
connect the second gate to the first centre point contact;
connect the third gate to a word line contact;
connect the fourth gate to the second centre point contact;
connect the fifth gate to the second centre point contact;
connect the sixth gate to the word line contact;
connect the first centre point contact to the second common drain contact;
connect the second centre point contact to the first common drain contact.

7. An SRAM cell according to claim 6, wherein each of the lateral gates is formed of polysilicon extending laterally across the fin.

8. An SRAM cell according to claim 7, wherein the interconnects include:
a first polysilicon extension extending longitudinally between the first and second gates to connect the first and second gates together; and
a second polysilicon extension extending longitudinally between the fourth and fifth gates to connect the fourth and fifth gates together.

9. An SRAM cell according to claim 8, wherein the interconnects include:
a first metallisation in a first metal layer connecting the first common drain, second polysilicon extension and first centre point contact; and
a second metallisation in a second metal layer connecting the second common drain, first polysilicon extension and the second centre point contact.

10. An SRAM cell according to claim 8, wherein the interconnects include a single metallisation layer having a plurality of regions, including:
a first region connecting the first polysilicon extension to the first centre point contact;
a second region connecting the second polysilicon extension to the second centre point contact;
a third metallisation region connecting the first common drain contact and the fourth or fifth gate; and
a fourth metallisation region connects the second common drain contact and the first or second gate.

11. An SRAM cell according to claim 6 wherein the interconnects include a single metallisation layer having a plurality of regions, including:
a first region connecting the first gate, second gate and first centre point contact;
a second region connecting the fourth gate, fifth gate and second centre point contact;
a third region connecting the first common drain contact and the fourth or fifth gate; and
a fourth region connecting the second common drain contact and the first or second gate.

12. A semiconductor device comprising a plurality of SRAM cells according to claim 1 arranged laterally and longitudinally across a substrate.

13. A semiconductor device according to claim 12 wherein the fins are regularly spaced laterally across the substrate, so that the lateral spacing between the aligned first, second and third fins of an SRAM cell and the aligned fourth, fifth and sixth fins of the SRAM cell is the same as the spacing between the aligned fins of the SRAM cell and the closest aligned fins of laterally adjacent SRAM cells.

14. A method of manufacturing a semiconductor device according to claim 13, comprising:
forming a lateral array of longitudinal fins regularly spaced across a substrate;
removing parts of the longitudinal fins to define the fins of a plurality of finFETs;
forming and patterning a gate insulator and polysilicon over the gate insulator to form the gates of the finFETs; and
forming and patterning at least one metallisation layer to connect the finFETs to form the SRAM cells.

15. A method according to claim 14 further comprising doping first regions of the fins to be the first conductivity type using a tilt angle of 40° to 50° ; and doping second regions of the fins to be the second conductivity type using a tilt angle of about 40° to about 50°.
